(19) United States
(12) Patent Application Publication
(10) Pub. No.: US 2025/0063821 A1
(43) Pub. Date: Feb. 20, 2025

(54) MANUFACTURING METHOD FOR HYBRID SOI SUBSTRATE

(71) Applicant: Taiwan Semiconductor Manufacturing Company, Ltd., Hsinchu (TW)

(72) Inventors: Hung-Wen Hsu, Tainan City (TW); Hung-Chang Chang, Tainan City (TW); Jiech-Fun Lu, Madou Township (TW)

(21) Appl. No.: 18/405,075

(22) Filed: Jan. 5, 2024

Related U.S. Application Data
(60) Provisional application No. 63/519,333, filed on Aug. 14, 2023.

(51) Int. Cl. H01L 27/12; C30B 25/04; C30B 33/10; H01L 21/02; H01L 21/308; H01L 21/762

(52) U.S. Cl. CPC H01L 27/1207; C30B 25/04; C30B 33/10; H01L 21/02636; H01L 21/308; H01L 21/7624

(57) ABSTRACT

A method of manufacturing a hybrid SOI substrate includes epitaxially growing a sacrificial layer and then an upper semiconductor layer over a semiconductor body. The sacrificial layer may be a heavily doped semiconductor. The heavy doping allows the sacrificial layer to be selectively etched while leaving the upper semiconductor layer largely intact. An SOI region of the semiconductor body is masked while the upper semiconductor layer and the sacrificial layer are etched from a peripheral region of the semiconductor body. A bulk semiconductor is then grown to replace the etched layers on the peripheral region. Holes are formed through the upper semiconductor layer in the SOI region and the sacrificial layer is etched from beneath the upper semiconductor. The holes may then be filled with dielectric leaving a cavity beneath the upper semiconductor layer in the SOI region.

### REFERENCE TO RELATED APPLICATIONS

This Application claims the benefit of U.S. Provisional Application No. 63/519,333, filed on Aug. 14, 2023, the contents of which are incorporated herein by reference in their entirety.

### BACKGROUND

Semiconductor devices are commonly manufactured on bulk semiconductor substrates. An alternative type of substrate is a semiconductor on insulator (SOI) substrate. SOI substrates include an upper layer of silicon, or some other semiconductor, separated by an insulating layer from an underlying semiconductor body. SOI substrates include partial depletion SOI substrates and full depletion SOI substrates. The difference is in the thickness of the upper semiconductor layer. If transistors disposed on the upper semiconductor layer have depletion regions shallower than the upper semiconductor layer, the substrate is a partial depletion SOI substrate. If the substrate is thinner so that the depletion regions extend through the full thickness of the upper semiconductor layer, the substrate is a full depletion SOI substrate.

For some applications, SOI substrates have advantages over bulk semiconductor substrates. For example, SOI substrates have lower parasitic capacitances than bulk semiconductor substrates. This advantage is more pronounced in circuits that operate at high frequencies. As frequencies increase, parasitic capacitances have more pronounced effects. Examples of circuits that operate at high frequencies and benefit from SOI substrates include circuits with radio frequency devices and the like.

### BRIEF DESCRIPTION OF THE DRAWINGS

Aspects of the present disclosure are best understood from the following detailed description when read with the accompanying figures. In accordance with standard industry practice, features are not drawn to scale. Moreover, the dimensions of various features within individual drawings may be arbitrarily increased or reduced relative to one-another to facilitate illustration or provide emphasis.

FIGS. 1A-C illustrate cross-sectional and plan views of an integrated circuit (IC) device according to some embodiments of the present disclosure. FIGS. 1A and 1B are cross-sectional views corresponding respectively to the lines A-A′ and B-B′ in the plan view of FIG. 1C.

FIGS. 2A-C illustrate cross-sectional and plan views of an IC device according to another embodiment of the present disclosure.

FIGS. 3A-C illustrate cross-sectional and plan views of an IC device according to another embodiment of the present disclosure.

FIGS. 4A-C illustrate cross-sectional and plan views of an IC device according to another embodiment of the present disclosure.

FIGS. 5A-C illustrate cross-sectional and plan views of an IC device according to another embodiment of the present disclosure.

FIGS. 6A-C illustrate cross-sectional and plan views of an IC device according to another embodiment of the present disclosure.

FIGS. 7-16 provide a series of cross-sectional views illustrating a method according to some embodiments of the present disclosure.

FIG. 17-19 are a series of cross-sectional views illustrating another embodiment, which is a variation of the method of FIGS. 7-16.

FIG. 20 provides a flow chart for a method according to some aspects of the present disclosure.

FIG. 21 provides a flow chart for a variation on the method of FIG. 20, which is another embodiment of the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact.

Spatially relative terms, such as “beneath,” “below,” “lower,” “above,” “upper”, and the like, may be used herein to describe one element or feature's relationship to another element(s) or feature(s) as illustrated in the figures. These spatially relative terms are intended to encompass different orientations of the device or apparatus in use or operation in addition to the orientation depicted in the figures. The device or apparatus may be otherwise oriented (rotated 90 degrees or at other orientations) and the spatially relative descriptors used herein may be interpreted accordingly. Terms “first”, “second”, “third”, “fourth”, and the like are merely generic identifiers and, as such, may be interchanged in various embodiments. For example, while an element (e.g., an opening) may be referred to as a “first” element in some embodiments, the element may be referred to as a “second” element in other embodiments.

Although SOI substrates are advantageous for radio frequency devices and the like, bulk semiconductor substrates have advantages for other types of devices. Bulk semiconductor substrates provide better thermal management, can be grounded for noise management, and lend themselves to forming a wider variety of devices than do SOI substrates. Given that SOI substrates and bulk substrates each provide advantages for different types of devices and that it is desirable to combine various device types of devices on single chips, there has been a long felt need for hybrid SOI substrates, which are substrates that include both an SOI region and a bulk substrate region. Radio frequency and like devices may be formed in the SOI region while logic and like devices may be formed in the bulk substrate region.

Some aspects of the present disclosure relate to a method of manufacturing a hybrid SOI substrate. The method includes forming a sacrificial layer over a semiconductor substrate. An upper semiconductor layer is epitaxially grown over the sacrificial layer. A first region, which will be the SOI region, is masked while the upper semiconductor layer and the sacrificial layer are etched from a second region, which will be the bulk substrate (logic) region. A bulk epitaxial layer is then grown in the logic region so as to replace the layers that were etched away. A mask is formed and used to etch holes. A liquid etchant is introduced through the holes and used to selectively etch the sacrificial layer from beneath the upper semiconductor layer leaving a cavity below the upper semiconductor layer in the SOI region. The holes may subsequently be sealed with dielectric. The dielectric that seals the holes forms dielectric vias.

In some embodiments, the holes are formed in both peripheral and central portions of the SOI region. Including holes in both the peripheral and central portions facilitates removing the sacrificial layer. In some embodiments, the holes are restricted to the periphery of the SOI region. Restricting the holes to the periphery of the SOI region increases the active device area of the SOI region.

In some embodiments, the cavity remains below the upper semiconductor layer in the SOI region after the holes are sealed. The cavity becomes filled with air or the like and provides a high degree of insulation between the upper semiconductor layer and the bulk semiconductor substrate. In some embodiments, the cavity is lined with the dielectric that is used to fill the holes. In some other embodiments, the cavity is filled with dielectric. The dielectric that fills the cavity may be the same as the dielectric that seals the holes.

In some embodiments, the hole filling process is combined with a process of forming shallow trench isolation STI structures in the logic region. The trenches for the STI structures are etched simultaneously with the holes. In some embodiments, the trenches and the holes are etched to equal depths. In some embodiments, the holes are etched more deeply. The trenches and the holes may be filled simultaneously and with the same dielectric. Forming these structures simultaneously reduces the overall processing time and the overall number of manufacturing steps.

The sacrificial layer is of a type that seeds the growth of the upper semiconductor layer. In some embodiments, the sacrificial layer is itself an epitaxially grown semiconductor layer but is grown with a higher dopant concentration than the upper semiconductor layer. In some embodiments, the sacrificial layer is heavily doped. Heavy doping provides a dopant concentration of at least about 1×10¹⁸ atoms/cm³. In some embodiments, the dopants are P-type dopants.

The upper semiconductor layer in the SOI region is masked when the bulk epitaxial layer is grown in the logic region, therefor, the semiconductor of the bulk epitaxial layer does not grow on top of the SOI region. Nevertheless, the bulk epitaxial layer may grow at the sides of the SOI region from the edges of the sacrificial layer and from the edges of the upper semiconductor layer. The growth may be particular rapid and polycrystalline, particularly at and above the interface between the sacrificial layer and the upper semiconductor layer. The side growth may result in bulges of polycrystalline semiconductor. In some embodiments, these bulges may be reduced by a planarization process. In some embodiments, the planarization process entirely removes the polycrystalline semiconductor that grows from the sides of the SOI region.

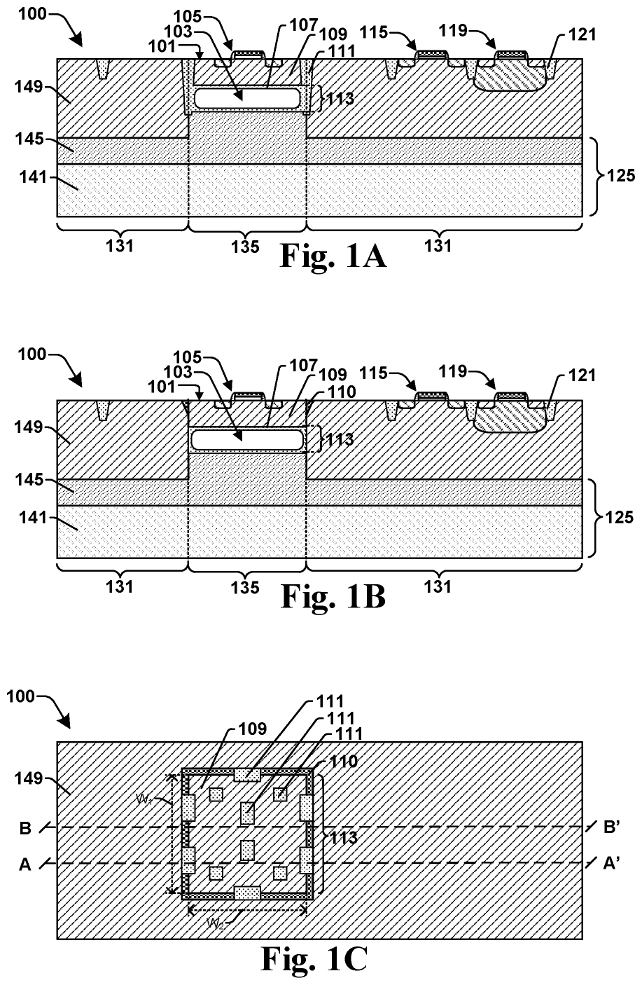

FIGS. 1A and 1B provide cross-sectional views and FIG. 1C provides a plan view of an integrated circuit (IC) device 100, which is an example of the present disclosure. FIG. 1A is a cross-section taken along the line A-A′ of FIG. 1C and FIG. 1B is a cross-section taken along the line B-B′ of FIG. 1C. The IC device 100 includes a semiconductor substrate 125 that comprises a semiconductor body 141 and an undoped semiconductor layer 145 epitaxially grown on the semiconductor body 141. The semiconductor body 141 may be a high resistivity bulk semiconductor. The semiconductor substrate 125 includes an SOI region 135 and a bulk substrate or logic region 131. The undoped semiconductor layer 145 is thicker and taller in the SOI region 135.

A bulk semiconductor layer 149 is disposed over the undoped semiconductor layer 145 in the logic region 131. An upper semiconductor layer 109 is disposed over the undoped semiconductor layer 145 in the SOI region. The bulk semiconductor layer 149 and the upper semiconductor layer 109 are of distinct provenances and have distinct compositions from the undoped semiconductor layer 145. In some embodiments, the bulk semiconductor layer 149 and the upper semiconductor layer 109 are lightly P-doped. In some embodiments, the bulk semiconductor layer 149 and the upper semiconductor layer have distinct dopant concentrations from one another.

The upper semiconductor layer 109 is separated from the undoped semiconductor layer 145 by an insulating layer 113. The insulating layer 113 includes a dielectric liner 107 and a cavity 103. The dielectric liner 107 surrounds the cavity 103 and joins with dielectric vias 111. The dielectric vias 111 extend from the surface 101 to the insulating layer 113. Some of the dielectric vias 111 are located on edges of the SOI region 135. Others of the dielectric vias 111 are with the SOI region 135 and pass through the upper semiconductor layer 109. The dielectric vias 111 are illustrated as rectangular structures but may be square or elongated so as to be trenches. Alternatively, the dielectric vias 111 may have other cross-sectional shapes, such as circular shapes, oval shapes, the like, or any other shape or combination of shapes.

As shown in FIGS. 1B and 1C, a polycrystalline structure 110 abuts the upper semiconductor layer 109 at the outer edges of the SOI region 135. The polycrystalline structure 110 may have a wedge shape that widens as it approaches the upper surface 101. The polycrystalline structure 110 is an artifact of forming the bulk semiconductor layer 149 using an epitaxial growth process after the upper semiconductor layer 109 is formed.

Semiconductor devices are disposed in the logic region 131. These may include transistors, diodes, capacitors, memory cells, thyristors, resistors, the like, or any combination thereof. An n-channel metal oxide semiconductor (NMOS) transistors 115 and a p-channel metal oxide semiconductor (PMOS) transistors 119 are illustrated by way of example. Isolation structure such as shallow trench isolation (STI) structures 121 may also be disposed in the logic region 131.

Radio frequency devices are formed in the SOI region 135. Examples of radio frequency devices include, without limitation, radio frequency transmitters, radio frequency receivers, radio frequency switches, low noise amplifiers, power amplifiers, mixers, voltage-controlled oscillators, phase shifters, resonators, filters, antennas, modulators, demodulators, or the like. As the term is used herein, radio frequency devices include microwave devices. A transistor 105, which is a component of a radio frequency device, is illustrated as an example.

The SOI region 135 may have a first width W₁ and a second width W₂. In some embodiments, the first width W₁ and the second width W₂ are each in the range from about 100 μm to about 1000 μm. In some embodiments, the SOI region 135 has an area in the range from about 0.01 mm² to about 1 mm². In some embodiments, the IC device 100 includes a plurality of SOI regions 135.

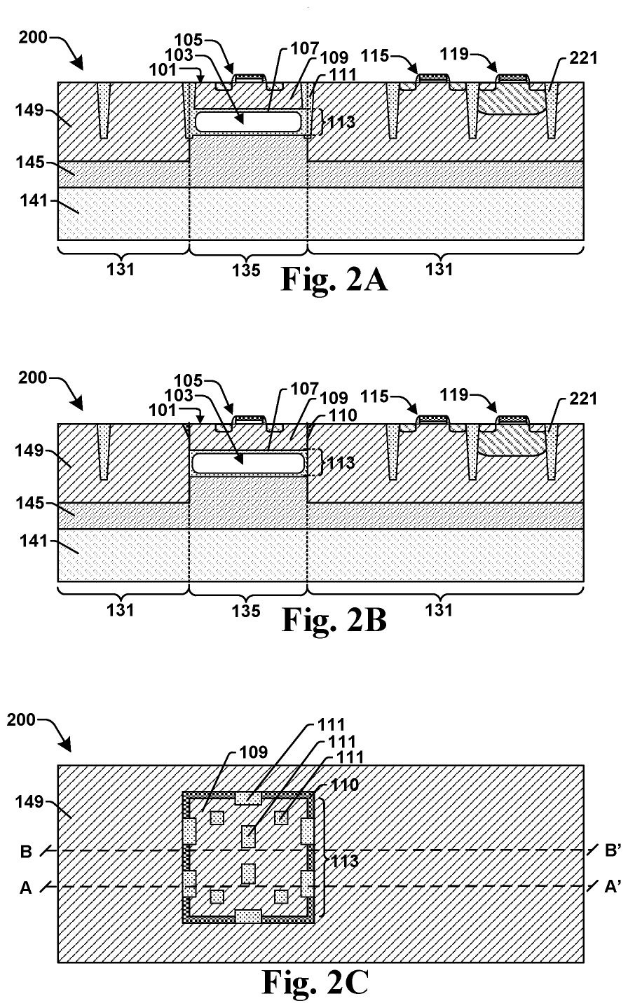

FIGS. 2A and 2B provide cross-sectional views, and FIG. 2C provides a plan view of an IC device 200, which is another example of the present disclosure. The IC device 200 is like the IC device 100 of FIGS. 1A-1C except that the IC device 200 has STI structures 221 that have the same depth and composition as the dielectric vias 111. The STI structures 221 may be produces by the same processing that produces the dielectric vias 111. The dielectric vias 111 may provide STI structures in the SOI region 135. On the other hand, the SOI region 135 and the logic region 131 may include other STI structures that are shallower than the dielectric vias 111 and may include other types of isolation structures. Shallower STI structures are potentially narrower than the dielectric vias 111 and so may take up less area.

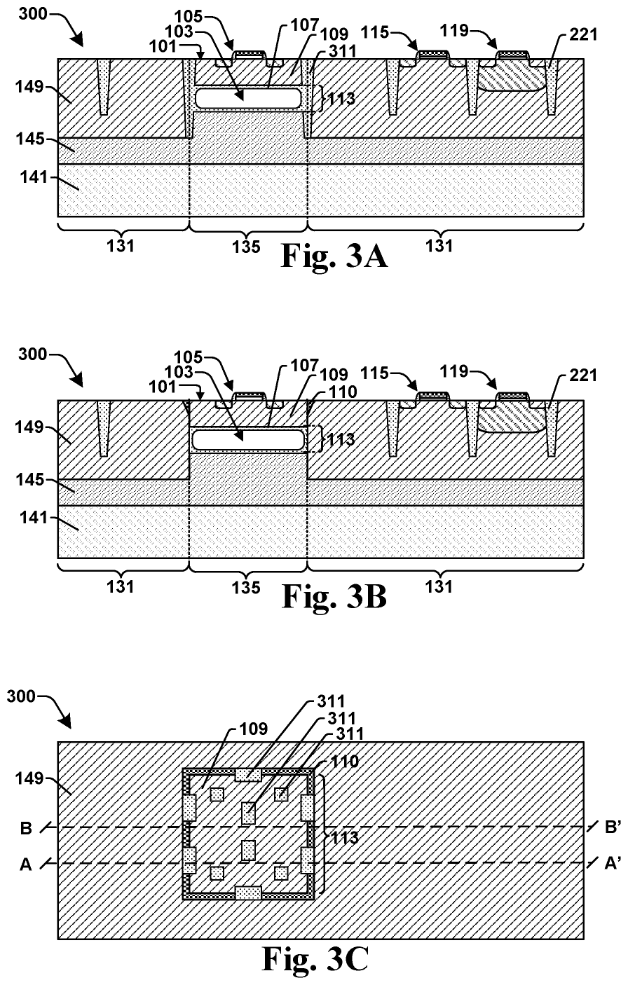

FIGS. 3A and 3B provide cross-sectional views, and FIG. 3C provides a plan view of an IC device 300, which is another example of the present disclosure. The IC device 300 is like the IC device 200 of FIGS. 2A-2C except that the IC device 300 has dielectric vias 311, which are deeper than the STI structures 221 and are also deeper the dielectric vias 111 of the IC device 100 of FIGS. 1A-1C. In some embodiments, the dielectric vias 311 have a depth equal to or greater than a thickness of the bulk semiconductor layer 149. Making the holes for the dielectric vias 311 deeper and/or wider facilitates removing sacrificial material so as to leave the cavity 103.

Etching holes for the dielectric vias 311 may overlap with etching trenches for the STI structures 221. Filling the holes to form the dielectric vias 311 may be simultaneous with filling the trench for the STI structures 221. Accordingly, the dielectric vias 311 and the STI structures 221 may have the same composition.

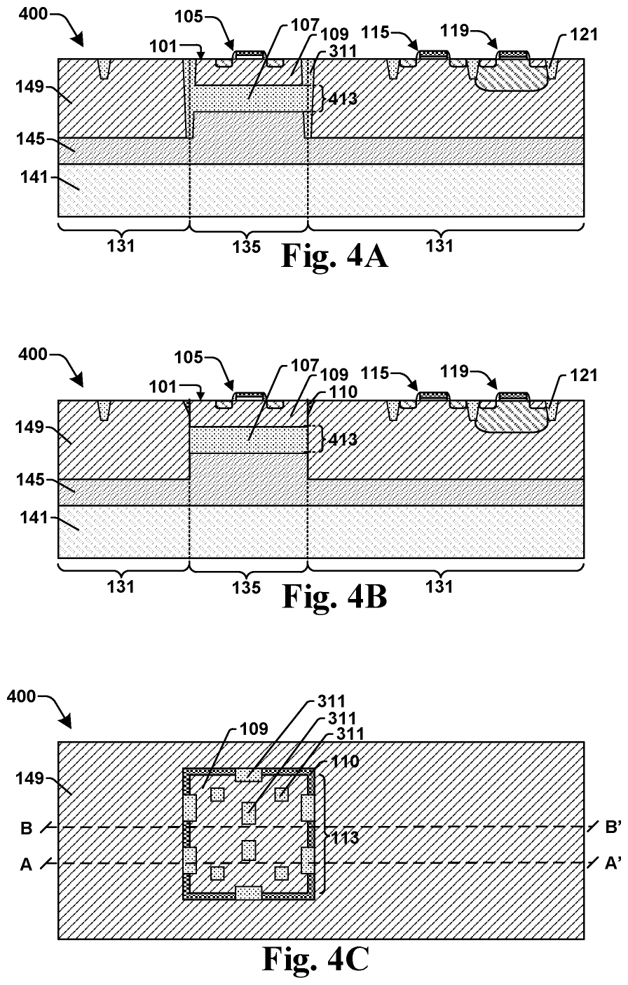

FIGS. 4A and 4B provide cross-sectional views, and FIG. 4C provides a plan view of an IC device 400, which is another example of the present disclosure. The IC device 400 is like the IC device 100 of FIGS. 1A-1C except that the IC device 400 has an insulating layer 413 that is completely filled with dielectric. While the insulating layer 113 of FIGS. 1A-1B which includes the cavity 103 provides the highest degree of insulation and the lowest parasitic capacitances, the insulating layer 413 which is filled with dielectric may provide devices with more consistent performance when the variability introduced by manufacturing processes is taken into consideration.

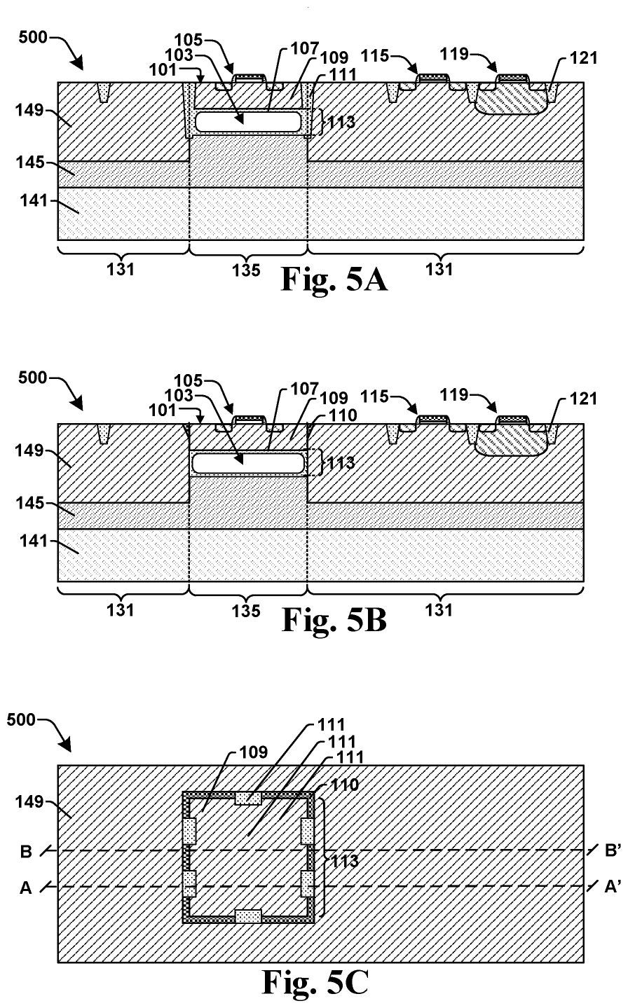

FIGS. 5A and 5B provide cross-sectional views, and FIG. 5C provides a plan view of an IC device 500, which is another example of the present disclosure. The IC device 500 is like the IC device 100 of FIGS. 1A-1C except that in the IC device 500 the dielectric vias 111 are restricted to the periphery of the SOI region 135. The dielectric vias 111 fill holes through which a sacrificial layer is etched so as to form the insulating layer 113. Having some of these holes in the center of the SOI region 135 can facilitate removing that sacrificial layer, however, if the holes may be restricted the periphery of the SOI region 135 so that the dielectric vias 111 are also restricted to the periphery of the SOI region 135, more area is left for devices within the SOI region 135.

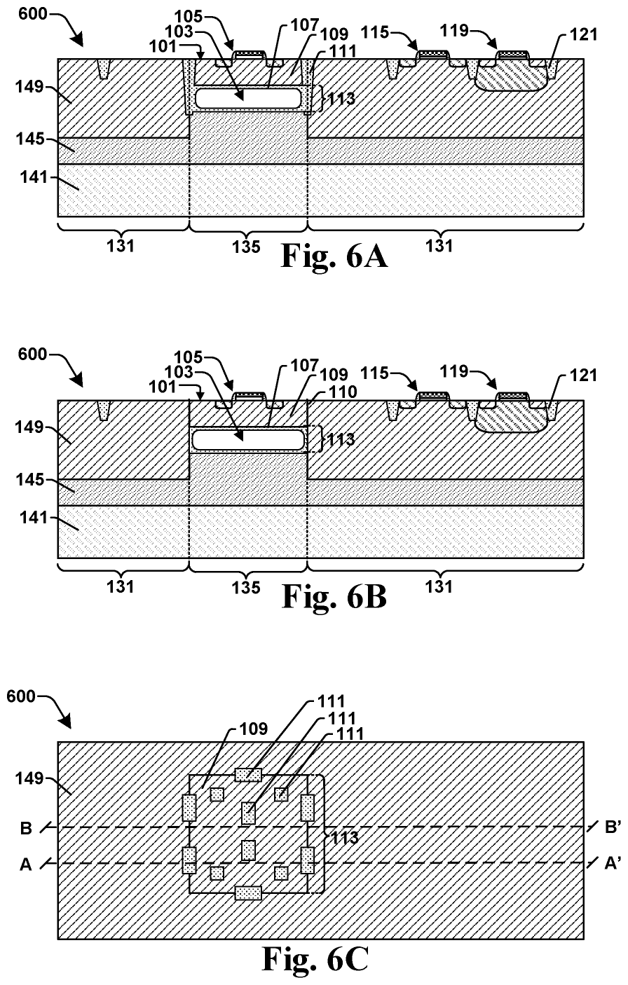

FIGS. 6A and 6B provide cross-sectional views, and FIG. 6C provides a plan view of an IC device 600, which is another example of the present disclosure. The IC device 600 is like the IC device 100 of FIGS. 1A-1C except that in the IC device 600 the polycrystalline structure 110 (see FIGS. 1B-1C) is absent. The polycrystalline structure 110 does not ordinarily affect device performance, but if there is some concern about the polycrystalline structure 110 it may be eliminated by suitable processing.

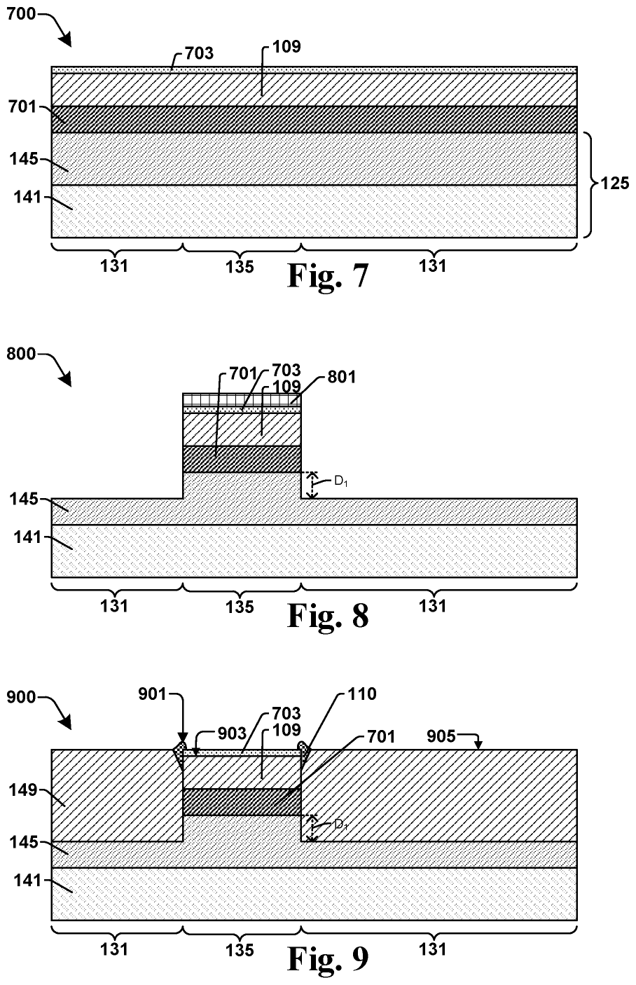

FIGS. 7-16 provide a series of cross-sectional views 700-1600 that illustrate an IC device at various stages of manufacture in accordance with a process of the present disclosure. Although FIGS. 7-16 are described in relation to a series of acts, it will be appreciated that the order of the acts may in some cases be altered and that this series of acts are applicable to structures other than the ones illustrated. In some embodiments, some of these acts may be omitted in whole or in part. Furthermore, FIGS. 7-16 are described in relation to a series of acts, it will be appreciated that the structures shown in FIGS. 7-16 are not limited to a method of manufacture but rather may stand alone as structures separate from the method.

As shown by the cross-sectional view 700 of FIG. 7, the method may begin with the formation of a series of layers over the semiconductor body 141. These may include the undoped semiconductor layer 145, a sacrificial layer 701, and the upper semiconductor layer 109, and a stop layer 703. Each of the undoped semiconductor layer 145, the sacrificial layer 701, and the upper semiconductor layer 109 is formed by an epitaxial growth process or the like. The stop layer 703 may include one or more layers formed by oxidation, chemical vapor deposition (CVD), physical vapor deposition (PVD), atomic layer deposition (ALD), the like, or any other suitable process.

The semiconductor body 141 is a bulk semiconductor substrate. The semiconductor body 141 may be silicon (Si), a group III-V semiconductor (e.g., GaAs) or some other binary semiconductor, a tertiary semiconductor (e.g., AlGaAs), a higher order semiconductor, the like, or any other suitable semiconductor. In some embodiments, the semiconductor body 141 is silicon (Si) or the like. In some embodiments, the semiconductor body 141 is a high resistivity substrate. A high resistivity substrate has fewer free charge carriers than a conventional substrate and reduces parasitic capacitances of a type that can affect radio frequency devices. In some embodiments, the semiconductor body 141 is a conventional substrate (not high resistivity). A conventional substrate is less expensive than a high resistivity substrate. The insulating layer 113 that includes the cavity 103 (see FIG. 1) may reduce parasitic capacitances to such a degree as to eliminate a need for a high resistivity substrate. In some embodiments, the semiconductor body 141 is lightly P-doped. A light P-type doping can facilitate grounding the semiconductor body 141.

The undoped semiconductor layer 145 is optional. It may be the same type of semiconductor as the semiconductor body 141 but is substantial or entirely free of dopants. Because it is undoped, the undoped semiconductor layer 145 has a lower concentration of crystal-originated particles than does the semiconductor body 141. Having this lower concentration of crystal-originated particles reduces leakage currents. In some embodiments, the undoped semiconductor layer 145 has a thickness in the range from about 0.5 μm to about 10 μm In some embodiments, the undoped semiconductor layer 145 has a thickness in the range from about 1 μm to about 3 μm, e.g., about 2 μm. If the thickness is too low, this layer may be etched through in the logic region 131 during subsequent process. Making this layer too thick may excessively increase processing time.

The sacrificial layer 701 may be any material that may be epitaxially grown, that supports the epitaxial growth of the upper semiconductor layer 109 as a single crystal layer, and has a higher etch susceptibility than the upper semiconductor layer 109 with respect to a suitable etchant. In some embodiments, the upper semiconductor layer 109 is a heavily doped semiconductor layer. In some embodiments, the dopant concentration is at least about 1×10¹⁸ atoms/cm³. In some embodiments, the dopant concentration is at least about 1×10¹⁹ atoms/cm³. In some embodiments, the dopants are P-type dopants. Examples of P-type dopants include boron (B), Gallium (Ga), Aluminum (Al), Indium (In), and the like. In some embodiments, the P-type dopant is boron (B). The thickness of the sacrificial layer 701 is selected in relation to a desired thickness of the insulating layer 113 (see FIG. 1). In some embodiments, the thickness of the sacrificial layer 701 is in the range from about 1 μm to about 5 μm. In some embodiments, the thickness of the sacrificial layer 701 is in the range from about 1.5 μm to about 3 μm.

The upper semiconductor layer 109 may be silicon (Si), a group III-V semiconductor (e.g., GaAs) or some other binary semiconductor, a tertiary semiconductor (e.g., AlGaAs), a higher order semiconductor, the like, or any other suitable semiconductor. In some embodiments, upper semiconductor layer 109 is silicon (Si) or the like. In some embodiments, the upper semiconductor layer 109 is the same type of semiconductor as the semiconductor body 141. In some embodiments, the upper semiconductor layer 109 is lightly P-doped. In some embodiments, the upper semiconductor layer 109 is formed to a thickness in the range from about 0.5 μm to about 5 μm. In some embodiments, the upper semiconductor layer 109 is formed to a thickness in the range from about 1 μm to about 2 μm. The upper semiconductor layer 109 may be thinned during processing, so the deposited thickness may be greater than a final thickness that is intended for that layer.

The stop layer 703 provides an etch stop layer that may be removed during subsequent processing. Because this layer will be removed during subsequent processing, its composition may be varied widely. In some embodiments, the stop layer 703 is a dielectric. Examples of dielectrics that may be suitable include silicon dioxide (SiO₂), silicon nitride (SiN), silicon carbide (SiC), combinations thereof, or the like. In some embodiments, the stop layer 703 is silicon dioxide (SiO₂) or the like. In some embodiments, the stop layer 703 is formed by plasma enhanced chemical vapor deposition (PECVD) from a tetraethyl orthosilicate (TEOS) precursor. Silicon dioxide (SiO₂) deposited by PECVD from TEOS has well defined physical properties. In some embodiments, the stop layer 703 has a thickness in the range from about 50 nm to about 1 μm.

As shown by the cross-sectional view 800 of FIG. 8, a mask 801 maybe formed so as to cover the SOI region 135 while an etch process is used to remove the stop layer 703, the upper semiconductor layer 109, and the sacrificial layer 701 from the logic region 131. The mask 801 may be a photoresist patterned by photolithography, the like, or any other type of mask patterned by any suitable process. The etch process may include dry etching, wet etching, or a combination thereof. In some embodiments, the etch process includes plasma etching or the like. The etch process may extend a depth D₁ below the sacrificial layer 701. In some embodiments, the depth D₁ is about halfway through the undoped semiconductor layer 145. In some embodiments, the depth D₁ is from about 100 nm to about 2 μm. In some embodiments, the depth D₁ is from about 500 nm to about 1500 nm. The contrast between the sacrificial layer 701 and the undoped semiconductor layer 145 may not be apparent during the etch process. Allowing the etch to proceed some distance into the undoped semiconductor layer 145 assures that the etch has extended through the sacrificial layer 701 so that it is completely removed from the logic region 131. After the etch process, the mask 801 may be stripped.

As shown by the cross-sectional view 900 of FIG. 9, the bulk semiconductor layer 149 is epitaxially grown over the structure shown by the cross-sectional view 800 of FIG. 8. The bulk semiconductor layer 149 grows on the undoped semiconductor layer 145 in the logic region 131 and on the sides of the SOI region 135 but does not ordinarily grow on the stop layer 703. The bulk semiconductor layer 149 is generally a single crystal structure, however, a polycrystalline structure 110 may grow from the sides of the SOI region 135. The bulk semiconductor layer 149 is grown to a thickness that is at least about equal to the combined thicknesses of the upper semiconductor layer 109, the sacrificial layer 701, and the depth D₁ so that an upper surface 905 of the bulk semiconductor layer 149 is at or above an upper surface 903 of the upper semiconductor layer 109. The polycrystalline structure 110 may form bulges 901 that extend higher, and in particular may extend above the stop layer 703.

The bulk semiconductor layer 149 may be silicon (Si), a group III-V semiconductor (e.g., GaAs) or some other binary semiconductor, a tertiary semiconductor (e.g., AlGaAs), a higher order semiconductor, the like, or any other suitable semiconductor. In some embodiments, bulk semiconductor layer 149 is silicon (Si) or the like. In some embodiments, the bulk semiconductor layer 149 is the same type of semiconductor as the upper semiconductor layer 109. In some embodiments, the bulk semiconductor layer 149 is silicon (Si) or the like. In some embodiments, the bulk semiconductor layer 149 is lightly P-doped.

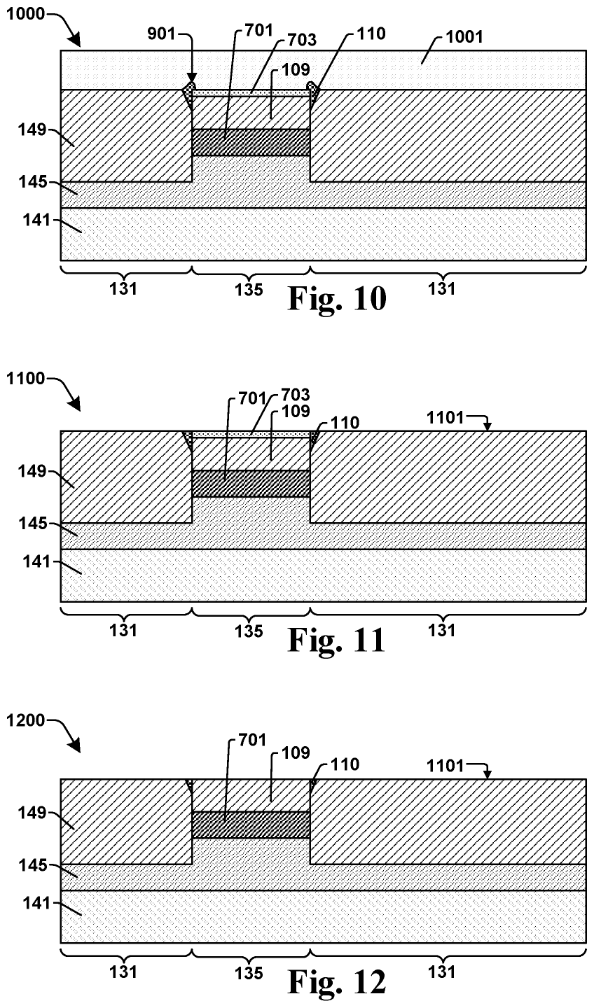

As shown by the cross-sectional view 1000 of FIG. 10, a leveling film 1001 may be formed over the structure shown by the cross-sectional view 900 of FIG. 9 so as to facilitate planarization of that structure. The leveling film 1001 may be formed by any suitable process. In some embodiments, the leveling film 1001 is formed from a liquid precursor using a spin on process. In some embodiments, the leveling film 1001 is a photoresist material or a bottom antireflective coating (BARC) material. In some embodiments, the leveling film 1001 is an organic polymer or the like.

As shown by the cross-sectional view 1100 of FIG. 11, the surface 1101 is recessed by etching that stops on the stop layer 703. This etching may remove the leveling film 1001. The etch process may include wet etching, dry etching, or a combination of wet and dry etching. In some embodiments, the etch process is plasma etching or the like.

As shown by the cross-sectional view 1200 of FIG. 12, the stop layer 703 (see FIG. 11) is removed and the surface 1101 is planarized. In some embodiments, the stop layer 703 is removed by wet etching prior to chemical mechanical polishing (CMP). Removing the stop layer 703 prior to CMP may result in a comparatively more level surface with comparatively less thinning of the upper semiconductor layer 109 than if the stop layer 703 is removed by CMP alone. This may facilitate control over the final thickness of the upper semiconductor layer 109. In some embodiments, a portion of the polycrystalline structure 110 remains after planarization, although the bulges 901 (see FIG. 9) are removed. In some embodiments, the planarization continues further so that that the polycrystalline structure 110 is removed entirely.

As shown by the cross-sectional view 1300 of FIG. 13, a photoresist mask 1307 may be formed and used to etch trenches 1305 in the logic region 131 and holes 1301 in and at the edges of the SOI region 135. The etch process may be a dry etch such as a plasma etch. After etching is complete, the photoresist mask 1307 may be stripped.

Optionally, a hard mask 1303 is also formed and subjected to the patterning process. The hard mask 1303 may include one or more layers of dielectric materials such as silicon dioxide (SiO₂), silicon nitride (SiN), or the like. In some embodiments, the hard mask 1303 includes a silicon dioxide (SiO₂) layer and a silicon nitride (SiN) layer, which facilitates the formation of isolation structures in the logic region 131. In some embodiments, the hard mask layer 1303 has a total thickness in the range from about 20 nm to about 200 nm. In some embodiments, the hard mask layer 1303 has a total thickness in the range from about 50 nm to about 100 nm. In some embodiments, the hard mask layer includes a silicon dioxide (SiO₂) layer having a thickness of about 20 nm or less and a silicon nitride (SiN) having a thickness of about 80 nm or greater.

The trenches 1305 may have a desired pattern for STI structures in the logic region 131. The holes 1301 may have any pattern suitable for providing access to the sacrificial layer 701. The holes 1301 may have the pattern of the dielectric vias 111 as shown in FIG. 1C, as shown in FIG. 5C, or any other suitable pattern. In some embodiments, the holes 1301 include holes within the interior of the SOI region 135. In some embodiments, the holes 1301 are restricted to the periphery of the SOI region 135.

As shown by the cross-sectional view 1400 of FIG. 14, the sacrificial layer 701 (see FIG. 13) may be etched away through the holes 1301 so to leave the cavity 103. The holes 1301 do not completely surround the SOI region 135 so that the structure in the interior of the SOI region 135 is not detached. The etch process may be a wet etch. In some embodiments, the wet etch uses HNA, which is a mixture of hydrofluoric acid (HF), nitric acid (HNO₃), and acetic acid (CH₃COOH). The proportions of these acids may be chosen so as to provide an etch selectivity of about 100:1, whereby the sacrificial layer 701 may be removed without significantly eroding the upper semiconductor layer 109.

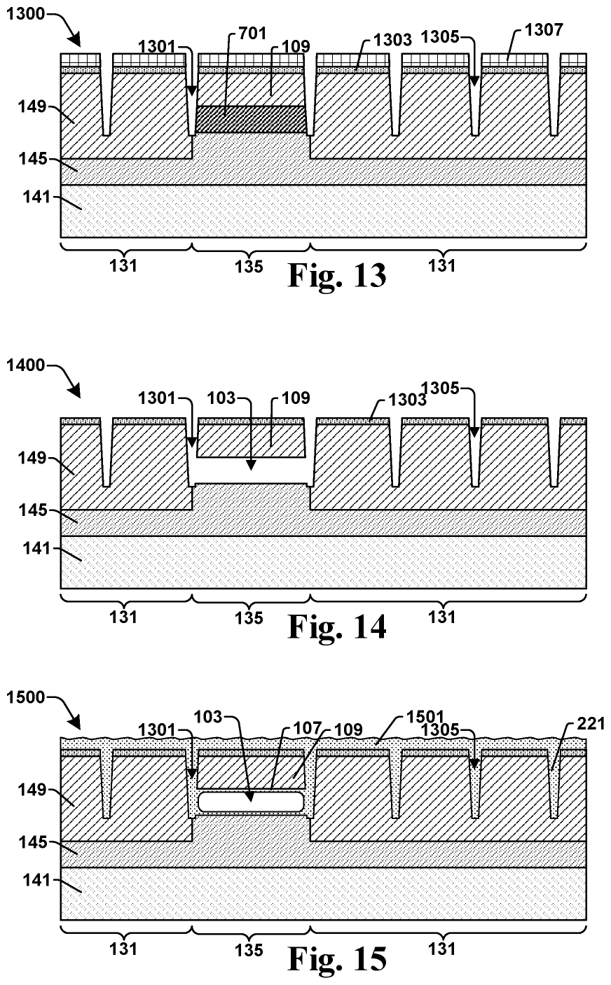

As shown by the cross-sectional view 1500 of FIG. 15, a dielectric 1501 may be deposited so as to seal or fill the holes 1301 and fill the trenches 1305. The dielectric 1501 may be any suitable dielectric. In some embodiments, the dielectric 1501 is silicon dioxide (SiO2) or the like. The dielectric 1501 may be deposited by CVD, PVD, ALD, the like, or any other suitable process. In some embodiments, the dielectric 1501 is silicon dioxide (SiO2) deposited using high-density plasma CVD (HDP-CVD), which is a process that combines aspects of plasma-enhanced CVD (PECVD) and sputtering. The HDP-CVD can provide good gap fill for the present application. In some embodiments, the deposition process is carried out in such a way that the dielectric 1501 forms the dielectric liner 107 and leaves the cavity 103. In some other embodiments, the process is carried out in such a way that the dielectric 1501 fills the cavity 103 (see FIGS. 4A-4B). The deposition process conditions may be adjusted to select between these results.

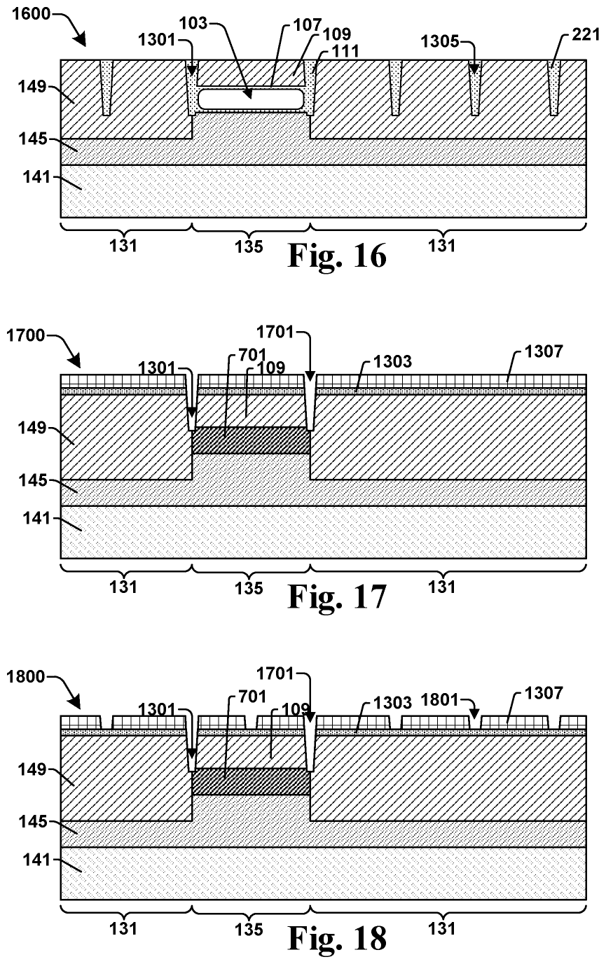

As shown by the cross-sectional view 1600 of FIG. 16, a planarization process such as CVD or the like may be carried out so as to remove excess dielectric 1501 and reduce the upper semiconductor layer 109 to a desired thickness. The dielectric 1501 that remains in the holes 1301 forms the dielectric vias 111 and the dielectric 1501 that remains in the trenches 1305 forms the STI structures 221. The planarization process may leave some of the polycrystalline structure 110 (not present in the plane of FIG. 16, but see, e.g., FIG. 12) or may remove the polycrystalline structure 110. In some embodiments, the final thickness of the upper semiconductor layer 109 is in the range from about 100 nm to about 200 nm. In some embodiments, the final thickness of the upper semiconductor layer 109 is in the range from about 50 nm to about 100 nm, e.g., about 75 nm. Additional processing may form logic devices in the logic region 131, radio frequency devices in the SOI region 135, and a metal interconnect structure (not shown) over both the SOI region 135 and the logic region 131.

FIGS. 17-19 provide a series of cross-sectional views 1700-1900 illustrating a variation of the foregoing process. With reference to FIG. 16, this variation allows the STI structures 221 to be made shallower than the dielectric vias 111 while still having extensive overlap between the processes that form these structures.

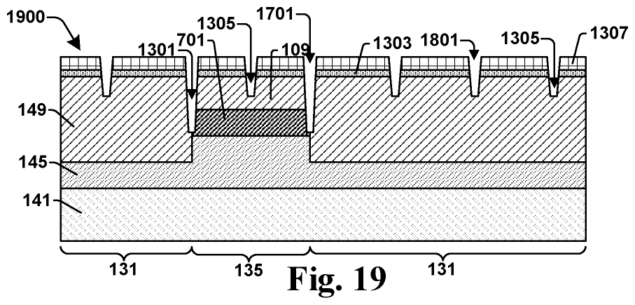

The variation begins with a variation from what is shown by the cross-sectional view 1300 of FIG. 13. As shown by the cross-sectional view 1700 of FIG. 17, the mask 1307 may initially have only the openings 1701 that correspond to the desired locations for the holes 1301 and etching may be carried out that only partially etches the holes 1301. As shown by the cross-sectional view 1800 of FIG. 18, additional openings 1801 may then be added to the mask 1307. As shown by the cross-sectional view 1900 of FIG. 19, further etching then takes place. The further etching completes formation of the holes 1301 while forming the trenches 1305. The trenches 1305 are subsequently filled to provide STI structures 121 (see FIG. 1) while the holes 1301 are being sealed. Some of the trenches 1305 may be in the SOI region 135 so that some of the STI structures 121 are formed in the SOI region 135. Additional processing takes place as shown by the cross-sectional views 1400-1600 of FIGS. 14-16.

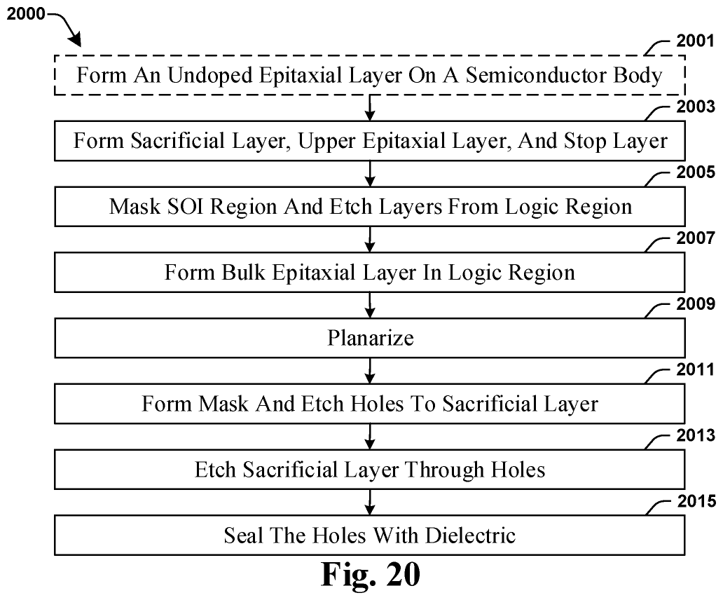

FIG. 20 provides a flow diagram for a method 2000 according to some embodiments of forming an IC device. While the method 2000 is illustrated and described as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

The method 2000 begins with an option step, act 2001, which is epitaxially growing an undoped semiconductor layer over a semiconductor body. The method 2000 continues with act 2003, sequentially forming a sacrificial layer, an upper semiconductor layer, and a stop layer. The cross-sectional view 700 of FIG. 7 provides an example of these processes.

Act 2005 is masking the SOI region and etching in the logic region to remove the layers that were formed by act 2003. The cross-sectional view 800 of FIG. 8 provides an example.

Act 2007 is forming a bulk epitaxial layer in the logic region. The stop layer may prevent this growth in the SOI region. The bulk epitaxial layer fills in the space vacated by the etching of act 2005. In some embodiments, a polycrystalline semiconductor growth occurs at the edges of the SOI region during this process. The cross-sectional view 900 of FIG. 9 provides an example.

Act 2009 is a planarization process. The process may include such actions as applying a leveling film, dry etching, wet etching, chemical mechanical polishing, or a combination thereof. The stop layer may facilitate control over this processing. The stop layer may also be removed during the planarization process. The cross-sectional views 1000-1200 of FIG. 10-12 provide an example.

Act 2011 is forming a mask and using it to etch holes through the upper semiconductor layer to provide access to the sacrificial layer that lies beneath. The cross-sectional view 1300 of FIG. 13 provides an example. In some embodiments, the holes extend through the sacrificial layer. In some embodiments, the holes extend about halfway or further into the undoped semiconductor layer. Making the holes deeper and wider facilitates the subsequent etch process. In some embodiments, the holes include holes through the interior of the SOI region. The IC device 100 of FIG. 1C provides an example in which the locations of the dielectric vias 111 correspond to the locations of these holes. In some embodiments, the holes are restricted to the periphery of the SOI region. The IC device 500 of FIG. 5C provides an example.

Act 2013 is etching away the sacrificial layer beneath the upper semiconductor layer. In some embodiments, this is a wet etch using HNO. The cross-sectional view 1400 of FIG. 14 provides an example.

Act 2015 is sealing the holes with dielectric. In some embodiments, sealing the holes fills the holes with dielectric and thereby creates dielectric vias that extend through the upper semiconductor layer. In some embodiments, sealing the holes leaves a cavity beneath the upper semiconductor layer. The cross-sectional views 1500-1600 of FIGS. 15-16 provide an example. In some embodiments, sealing the holes fills the cavity with dielectric. The IC device 400 of FIGS. 4A-4C provides an example.

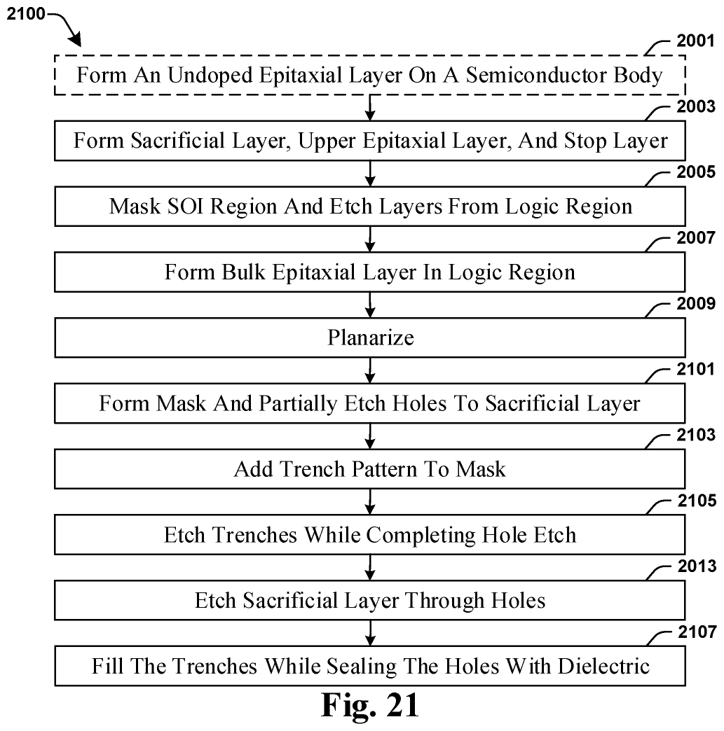

FIG. 21 provides a flow chart of a method 2100, which is a variation of the foregoing method 2000. The method 2100 allows STI structures that are shallower than the dielectric vias to be formed simultaneously with the dielectric vias. The IC device 100 of FIGS. 1A-1C and the IC device 300 of FIGS. 3A-3C provide examples of devices that can be manufactured using this variation.

The variation begins at act 2101, in which a mask is formed having openings corresponding to holes for accessing the sacrificial layer and using that mask to partially etch those holes. The cross-sectional view 1700 of FIG. 17 provides an example. The variation continues with act 2103, which is adding additional openings to the mask corresponding to desired locations for STI structures. The cross-sectional view 1800 of FIG. 18 provides an example. Act 2105 is completing the hole etch while etching the trenches. The cross-sectional view 1900 of FIG. 19 provides an example. Act 2013 follows, which is etching away the sacrificial layer through the holes just as in the method 2000. Act 2107 of the method 2100 corresponds with act 2015 of the method 2000, except the in act 2107, the trenches are filled to form STI structures at the same time the holes are being sealed.

Some aspects of the present disclosure relate to a hybrid SOI substrate to a semiconductor that includes a first region and a second region, an upper semiconductor layer over the first region, and a bulk semiconductor layer over the second region. The upper semiconductor layer is separated from the semiconductor substrate by a cavity. The bulk semiconductor layer extends from a height below the cavity to a height equal to an upper surface of the upper semiconductor layer. In some embodiments, a dielectric via extends through a thickness of the upper semiconductor layer. The dielectric via is continuous with a dielectric that lines the cavity and has the same composition.

Some aspects of the present disclosure relate to an integrated circuit device that includes a semiconductor substrate. The semiconductor substrate has a first region and a second region. In the first region there is an insulating layer separating an upper semiconductor layer from the semiconductor substrate. In the second region, the is a bulk semiconductor layer over the semiconductor substrate. The bulk semiconductor layer is at equivalent heights with the insulating layer and the upper semiconductor layer. A polycrystalline semiconductor structure is disposed between the upper semiconductor layer and the bulk semiconductor layer at a side of the first region. In some embodiments, the semiconductor substrate comprises a semiconductor body and an undoped semiconductor layer over the semiconductor body. The undoped semiconductor layer has a lower concentration of crystal-originated particles than does the semiconductor body.

Some aspects of the present disclosure relate to a method of manufacturing an integrated circuit device. The method includes forming a sacrificial layer over a semiconductor body that includes a first region and a second region and epitaxially growing an upper semiconductor layer over the sacrificial layer. The first region is masked while etching through the upper semiconductor layer and the sacrificial layer in the second region. A bulk semiconductor layer is then grown in the second region. The sacrificial layer is then etched through holes that extend through a thickness of the upper semiconductor layer so as from a cavity beneath the upper semiconductor layer. The holes are subsequently sealed with dielectric.

In some embodiment, the method further includes planarizing so that the bulk semiconductor layer in the second region is coplanar with the upper semiconductor layer in the first region. Planarization may take place before etching to form the cavity. In some embodiments, the semiconductor body is a high resistivity substrate. In some embodiments, the method further includes epitaxially growing an undoped semiconductor layer over the semiconductor body prior to forming the sacrificial layer. Etching through the upper semiconductor layer and the sacrificial layer in the second region may comprise etching into the undoped epitaxial layer.

In some embodiments, polycrystalline semiconductor grows from an edge of the first region while epitaxially growing the bulk semiconductor layer in the second region. In some embodiments, the polycrystalline semiconductor forms a bulge that is higher than the mask and the method further comprises a planarization process that includes forming a sacrificial coating from a liquid precursor, etching so as to recess the sacrificial coating, and chemical mechanical polishing. In some embodiments, planarization entirely removes the polycrystalline semiconductor.

In some embodiments, forming the sacrificial layer comprises epitaxially growing the sacrificial layer, and the sacrificial layer is heavily doped. In some embodiments, etching the sacrificial layer comprises etching with a mixture of hydrofluoric, acetic, and nitric acids. In some embodiments, the holes are at a periphery of the first region. In some embodiments, etching the holes includes forming a second mask, forming first openings in the second mask in the first region, forming second opening in the second mask in the second region, and etching through the first openings to form the holes and etching through the second openings to form trenches. In some embodiments, the trenches are filled to provide shallow trench isolation structures in the second region. In some embodiments, a process of sealing the holes fills the trenches. In some embodiments, the method further includes etching through the first openings prior to forming the second openings, whereby the holes are deeper than the trenches. In some embodiments, a process of sealing the holes with dielectric fills the cavity with dielectric.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A hybrid SOI substrate, comprising:
a semiconductor substrate, wherein the semiconductor substrate includes a first region and a second region;
an upper semiconductor layer in the first region, wherein the upper semiconductor layer is separated from the semiconductor substrate by a cavity; and
a bulk semiconductor layer over the semiconductor substrate in the second region, wherein the bulk semiconductor layer extends from a height below the cavity to a height of an upper surface of the upper semiconductor layer.

2. The hybrid SOI substrate of claim 1, further comprising a dielectric via that extends through a thickness of the upper semiconductor layer, wherein the dielectric via is continuous with and is of a same composition as a dielectric that lines the cavity.

3. An integrated circuit device, comprising:
a semiconductor substrate, wherein the semiconductor substrate includes a first region and a second region;
an upper semiconductor layer over the first region;
an insulating layer between the upper semiconductor layer and the semiconductor substrate in the first region;
a bulk semiconductor layer over the semiconductor substrate in the second region, wherein the bulk semiconductor layer is at heights equivalent with the insulating layer and the upper semiconductor layer; and
a polycrystalline semiconductor structure between the upper semiconductor layer and the bulk semiconductor layer at a side of the first region.

4. The integrated circuit device of claim 3, wherein:
the semiconductor substrate comprises a semiconductor body and an undoped semiconductor layer disposed over the semiconductor body; and
the undoped semiconductor layer has a lower concentration of crystal-originated particles than does the semiconductor body.

5. A method of manufacturing an integrated circuit device, the method comprising:
forming a sacrificial layer over a semiconductor body that comprises a first region and a second region;
epitaxially growing an upper semiconductor layer over the sacrificial layer;
forming a mask over the first region;
etching through the upper semiconductor layer and the sacrificial layer in the second region while the first region is masked;
epitaxially growing a bulk semiconductor layer in the second region;
etching holes, wherein the sacrificial layer is exposed through the holes;
etching the sacrificial layer through the holes so as to form a cavity beneath the upper semiconductor layer in the first region; and
sealing the holes with dielectric.

6. The method of claim 5, further comprising planarizing so that the bulk semiconductor layer in the second region is coplanar with the upper semiconductor layer in the first region.

7. The method of claim 5, wherein the semiconductor body is a high resistivity substrate.

8. The method of claim 5, further comprising epitaxially growing an undoped semiconductor layer over the semiconductor body prior to forming the sacrificial layer.

9. The method of claim 8, etching through the upper semiconductor layer and the sacrificial layer in the second region comprises etching into the undoped semiconductor layer.

10. The method of claim 5, wherein polycrystalline semiconductor grows from an edge of the first region while epitaxially growing the bulk semiconductor layer in the second region.

11. The method of claim 10, wherein the polycrystalline semiconductor forms a bulge that is higher than the mask and the method further comprises a planarization process that includes forming a sacrificial coating from a liquid precursor, etching so as to recess the sacrificial coating, and chemical mechanical polishing.

12. The method of claim 11, wherein planarization entirely removes the polycrystalline semiconductor.

13. The method of claim 5, wherein forming the sacrificial layer comprises epitaxially growing the sacrificial layer, and the sacrificial layer is heavily doped.

14. The method of claim 5, wherein etching the sacrificial layer comprises etching with a mixture of hydrofluoric, acetic, and nitric acids.

15. The method of claim 5, wherein the holes are at a periphery of the first region.

16. The method of claim 5, wherein etching the holes comprises:
forming a second mask;
forming first openings in the second mask in the first region;
forming second openings in the second mask in the second region; and
etching through the first openings to form the holes and etching through the second openings to form trenches.

17. The method of claim 16, wherein the trenches are filled to provide shallow trench isolation structures in the second region.

18. The method of claim 16, wherein a process of sealing the holes fills the trenches.

19. The method of claim 16, further comprising etching through the first openings prior to forming the second openings, whereby the holes are deeper than the trenches.

20. The method of claim 5, wherein a process of sealing the holes with dielectric fills the cavity with dielectric.
